(19) United States
(12) Patent Application Publication
(10) Pub. No.: US 2005/0260829 A1
(43) Pub. Date: Nov. 24, 2005

(54) Manufacturing method of a semiconductor device

(76) Inventors: Toshihide Uematsu, Hinode (JP); Chuichi Miyazaki, Akishima (JP); Yoshiyuki Abe, Hinode (JP); Minoru Kimura, Tachikawa (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/119,930

(22) Filed: May 3, 2005

(30) Foreign Application Priority Data
May 20, 2004 (JP) 2004-150048

(51) Int. Cl. H01L 21/46

(52) U.S. Cl. 438/460

(57) ABSTRACT

The reliability of a thin semiconductor device is to be improved. A tape having a ring affixed to an outer periphery thereof is affixed to a main surface of a semiconductor wafer, and, in this state, a back surface of the semiconductor wafer is subjected to grinding and polishing to thin the wafer. Thereafter, the semiconductor wafer is conveyed to a dicing apparatus in a state in which the tape with the ring is affixed to the wafer main surface without peeling of the tape, and dicing is performed from the back surface side of the semiconductor wafer to divide the wafer into individual semiconductor chips. With this method, handling of the thin semiconductor wafer by rear surface processing can be facilitated. Besides, the manufacturing process can be simplified because the replacement of the tape is not needed at the time of shift from rear surface processing to the dicing process.

### CROSS-REFERENCE TO RELATED APPLICATION

The present application claims priority from Japanese patent application No. 2004-150048, filed on May 20, 2004, the content of which is hereby incorporated by reference into this application.

### BACKGROUND OF THE INVENTION

The present invention relates in general to a semiconductor device manufacturing technique and, more particularly, to a technique which may be used for thinning a semiconductor device.

A conventional back-end process in the manufacture of a semiconductor device is carried out as follows. First, a tape is affixed to a main surface of a semiconductor wafer, and then a back surface of the semiconductor wafer is subjected to grinding and then to polishing. Subsequently, the tape is peeled from the main surface of the semiconductor wafer, then the back surface of the semiconductor wafer is affixed to a dicing tape, and, thereafter, a dicing blade is positioned in a cutting region on the main surface of the semiconductor wafer and the wafer is cut with the blade for division into individual semiconductor chips. Thereafter, each semiconductor chip on the dicing tape is picked up while being vacuum-sucked by a collet and is accommodated within a pocket formed in a conveyance tray or is mounted onto a desired substrate.

Such a back-end process in the manufacture of a semiconductor device is described, for example, in Japanese Unexamined Patent Publication No. 2003-303921. A back-end process including the above-described tape affixing step for the main surface of the semiconductor wafer and the above-described pick-up step is disclosed in this publication (see Patent Literature 1).

The dicing technique is described, for example, in Japanese Unexamined Patent Publication No. Hei 7(1995)-74131. According to the dicing technique disclosed in this publication, in a state in which a wafer surface is affixed to a dicing tape, a back surface of the wafer is subjected to polishing or etching, and, thereafter, dicing is performed from the back surface side of the wafer while monitoring scribing lines formed on the wafer surface (see Patent Literature 2).

[Patent Literature 1] Japanese Unexamined Patent Publication No. 2003-303921

[Patent Literature 2] Japanese Unexamined Patent Publication No. Hei 7(1995)-74131

### SUMMARY OF THE INVENTION

To meet the recent demand for a reduction in weight, thickness and length of semiconductor devices, there is a tendency to effect thinning of semiconductor chips which constitute semiconductor devices. For example, in a semiconductor chip called a SIP (System In Package), a reduction in the thickness of semiconductor chips is required because plural semiconductor chips are stacked. However, the present inventors have found that an attempt to meet such a demand for the thinning of semiconductor chips encounters the following problems in the back-end process during manufacture of the semiconductor device.

In the foregoing back grinding and polishing steps, a thin semiconductor wafer, which is as thin as about 220 to 280 μm is further thinned to about half, i.e., about 100 μm, or less to provide an ultra-thin semiconductor wafer. However, the tape affixed to the main surface of the semiconductor wafer cannot be very thick from the standpoint of ensuring easiness of subsequent peeling of the tape. Therefore, as the semiconductor wafer becomes thinner, it is impossible, with only the tape affixed to the wafer main surface, to fully support the semiconductor wafer after the back grinding and polishing steps. Consequently, it becomes difficult to transfer the semiconductor wafer to the subsequent step in the manufacture. In more particular terms, since the tape has a lower rigidity than the semiconductor wafer, the semiconductor wafer, after the back grinding and polishing steps, warps while following the shape of the affixed tape, thus giving rise to the problem that the semiconductor wafer may crack during its transfer.

In the semiconductor device manufacturing process, there is a tendency to increase the diameter of a semiconductor wafer in order to increase the number of semiconductor chips that are capable of being obtained from a single semiconductor wafer, thereby to improve the production yield of semiconductor devices. But, the above-described problem becomes more and more conspicuous with an increase in the diameter of the semiconductor wafer.

According to the existing grinding/polishing apparatus used in the above-described back grinding and polishing steps, the thickness of an object to be subjected to grinding and polishing is recognized by the difference between the height of a back surface of a semiconductor wafer and the height of an upper surface of a table to which the semiconductor wafer is fixed. That is, the thickness of the object to be subjected to grinding and polishing, which the grinding/polishing apparatus recognizes, is equal not only to the thickness of the semiconductor wafer, but to the sum of the wafer thickness and the tape thickness. Consequently, there arises a problem in that, if the accuracy of the tape thickness varies, the accuracy of the wafer thickness also varies. Particularly, as the semiconductor wafer becomes thinner, the relative thickness of the tape affixed to the main surface of the semiconductor wafer increases, so that variations in the tape thickness accuracy come to be further actualized, thus leading to the problem that the semiconductor wafer grinding accuracy and polishing accuracy are deteriorated.

In the semiconductor chip pickup step, subsequent to the dicing step, each semiconductor chip is thrust up by a pin from its back surface side in order to facilitate removal of the semiconductor chip. However, since the semiconductor chip is thin, it may be cracked when it is thrust up with a pin.

Further, at the time of picking up a semiconductor chip by use of a collet, after the dicing step, and when inserting it into a pocket formed in a conveyance tray, the semiconductor chip becomes difficult to separate from the collet due to a sucking effect. To avoid such an inconvenience, there sometimes is a case where air is reversely jetted outward from the collet. In this case, there arises the problem that other semiconductor chips that have already been received within the other pockets in the conveyance tray move of the pockets under the influence of the air. Moreover, within the conveyance tray during conveyance, there occurs the problem that semiconductor chips move up, down, to the right, and to the left and strike against inner wall surfaces of pockets formed in the conveyance tray, resulting in the semiconductor chips being cracked or chipped if they are thin.

It is an object of the present invention to provide a technique which is capable of improving the reliability of a thin semiconductor device.

It is another object of the present invention to provide a technique which is capable of improving the yield of a thin semiconductor wafer.

The above and other objects and novel features of the present invention will become apparent from the following description and the accompanying drawings.

A typical mode of the present invention as disclosed herein will be outlined below.

A semiconductor device manufacturing method according to the present invention comprises the steps of grinding and polishing a back surface of a semiconductor wafer in a state in which a tape having a frame portion is affixed to a main surface of the semiconductor wafer, and dividing the semiconductor wafer with the tape affixed thereto into individual semiconductor chips. More specifically, the semiconductor device manufacturing method calls for the provision of a semiconductor wafer having a main surface and a back surface opposite to the main surface, and includes the steps of forming semiconductor chips on the main surface of the semiconductor chip, affixing a tape having a frame portion along an outer periphery thereof to the main surface of the semiconductor wafer, grinding and thereafter polishing the back surface of the semiconductor wafer with the tape affixed to the wafer main surface, cutting the semiconductor wafer with the tape affixed to the wafer main surface to divide the wafer into individual semiconductor chips, and, thereafter, taking out the semiconductor chips.

The following is a brief description of effects obtained by the typical mode of the present invention as disclosed herein.

After the back surface of the semiconductor wafer is subjected to grinding and polishing in a state in which a tape having a frame portion is affixed to the wafer main surface, the semiconductor wafer with the tape affixed thereto is cut into individual semiconductor chips, whereby it is possible to suppress or prevent quality deterioration of the thin semiconductor wafer or semiconductor chips in the back-end process, and, hence, it is possible to improve the reliability of a thin semiconductor device.

Further, by conveying the semiconductor wafer in a state in which a tape having a frame portion is affixed to the wafer main surface, it is possible to suppress or prevent cracking of the semiconductor wafer, and, hence, it is possible to improve the production yield of a thin semiconductor device.

### BRIEF DESCRIPTION OF THE DRAWINGS

FIG. 1 is a flow chart showing a semiconductor device manufacturing process according to an embodiment of the present invention;

FIG. 2 is an overall plan view of a main surface of a semiconductor wafer after a front-end process shown in FIG. 1;

FIG. 3 is a sectional view taken on line X1-X1 in FIG. 2;

FIG. 4 is an enlarged plan view of a principal portion of an example of the semiconductor wafer shown in FIG. 2;

FIG. 5 is a sectional view taken on line X2-X2 in FIG. 4;

FIG. 6 is an enlarged plan view of a principal portion of another example of the semiconductor wafer shown in FIG. 2;

FIG. 7 is a sectional view taken on line X3-X3 in FIG. 6;

FIG. 8 is an overall plan view of a jig with a semiconductor wafer affixed thereto;

FIG. 9 is a sectional view taken on line X4-X4 in FIG. 8;

FIG. 10 is a sectional view taken on line X4-X4 in FIG. 8 showing another example;

FIG. 11 is a sectional view showing an example of the process of measuring the thickness of a semiconductor wafer;

FIG. 12 is an enlarged plan view of a principal portion in the semiconductor wafer thickness measurement shown in FIG. 11;

FIG. 13 is a diagram showing a rear surface processing of the semiconductor wafer;

FIG. 14 is a diagram showing the rear surface processing;

FIG. 15 is a diagram showing a pattern recognizing step for recognizing patterns formed on a main surface of the semiconductor wafer;

FIG. 16 is a diagram showing a dicing step in the manufacture of the semiconductor wafer;

FIG. 17 is a diagram showing the dicing step which follows the steps shown in FIG. 16;

FIG. 18 is a diagram showing another dicing step for the semiconductor wafer;

FIG. 19 is a diagram showing the dicing step which follows the steps shown in FIG. 18;

FIG. 20 is a diagram showing a semiconductor chip pickup step;

FIG. 21 is a diagram showing the pickup step which follows the steps shown in FIG. 20;

FIG. 22 is a diagram showing the pickup step which follows the steps shown in FIG. 21;

FIG. 23 is a diagram showing another example of a semiconductor chip pickup step;

FIG. 24 is a diagram showing the pickup step which follows the steps shown in FIG. 23;

FIG. 25 is a diagram showing the pickup step which follows the steps shown in FIG. 24;

FIG. 26 is a diagram showing a die bonding step in the manufacture of the semiconductor chip;

FIG. 27 is a diagram showing the die bonding step which follows the steps shown in FIG. 26;

FIG. 28 is a diagram showing a wire bonding step which follows the die bonding step shown in FIG. 27;

FIG. 29 is a sectional view showing an example of a semiconductor device manufactured by the semiconductor device manufacturing method embodying the present invention;

FIG. 30 is a sectional view of a principal portion of an ordinary type of a conveyance tray;

FIG. 31 is a diagram which illustrates a drawback of the conveyance tray shown in FIG. 30;

FIG. 32 is a diagram which illustrates another drawback of the conveyance tray shown in FIG. 30;

FIG. 33 is an overall plan view of a main surface of a conveyance tray used in a semiconductor device manufacturing method according to another embodiment of the present invention;

FIG. 34 is an overall plan view of a back surface of the conveyance tray shown in FIG. 33;

FIG. 35 is a sectional view taken on line X5-X5 in FIGS. 33 and 34;

FIG. 36 is a sectional view showing the conveyance tray of FIGS. 33 to 35 with the tape removed;

FIG. 37 is an overall plan view showing the main surface of the conveyance tray of FIG. 33 with semiconductor chips accommodated therein in two stages;

FIG. 38 is a sectional view taken on line X6-X6 in FIG. 37;

FIG. 39 is an enlarged sectional view of a principal portion, showing a modification of tape construction of the conveyance tray;

FIG. 40 is a sectional view of a principal portion of the conveyance tray in a step of accommodating a semiconductor chip in the conveyance tray;

FIG. 41 is a sectional view of the principal portion of the conveyance tray in the semiconductor chip accommodating step which follows the steps shown in FIG. 40;

FIG. 42 is a diagram illustrating how to check back surfaces of the semiconductor chip accommodated in the conveyance tray;

FIG. 43 is a diagram showing a step of measuring the thickness of a semiconductor wafer in a semiconductor device manufacturing process according to a further embodiment of the present invention;

FIG. 44 is a diagram showing a step of measuring the thickness of a semiconductor wafer in a semiconductor device manufacturing process according to a still further embodiment of the present invention;

FIG. 45 is a sectional view of a semiconductor wafer in a semiconductor device manufacturing process according to a still further embodiment of the present invention;

FIG. 46 is a sectional view of the semiconductor wafer in the semiconductor device manufacturing process which follows the steps shown in FIG. 45; and

FIG. 47 is a sectional view of the semiconductor wafer in the semiconductor device manufacturing process which follows the steps shown in FIG. 46.

### DETAILED DESCRIPTION OF PREFERRED EMBODIMENTS

Where required for convenience' sake, the subject matter of the present invention will be described while being divided into plural sections or embodiments, but unless otherwise mentioned, they are not unrelated to one another, but are in a relation such that one is a modification, a detailed description, or a supplementary explanation, of part or the whole of another. In the following description of the embodiments, when reference is made to a number of elements (including the number, numerical value, quantity, and range), no limitation is made to the number referred to, but numerals above and below the number referred to will do as well, unless otherwise mentioned and except for the case where it is basically evident that a limitation is made to the number referred to. Further, it goes without saying that in the following description of the embodiments, constituent elements (including constituent steps) are not always essential, unless otherwise mentioned and except for the case where they are obviously considered basically essential. Likewise, it is to be understood that when reference is made to the shapes and positional relation of constituent elements in the following description of the embodiments, those substantially closely similar to or resembling such shapes, etc. are also included, unless otherwise mentioned and except for the case where a negative answer basically obviously results. This is also true of the foregoing numerical value and range. Moreover, in all of the drawings, portions having the same functions are identified by like reference numerals, and repeated explanations thereof will be omitted. Embodiments of the present invention will be described in detail hereinunder with reference to the accompanying drawings.

### First Embodiment

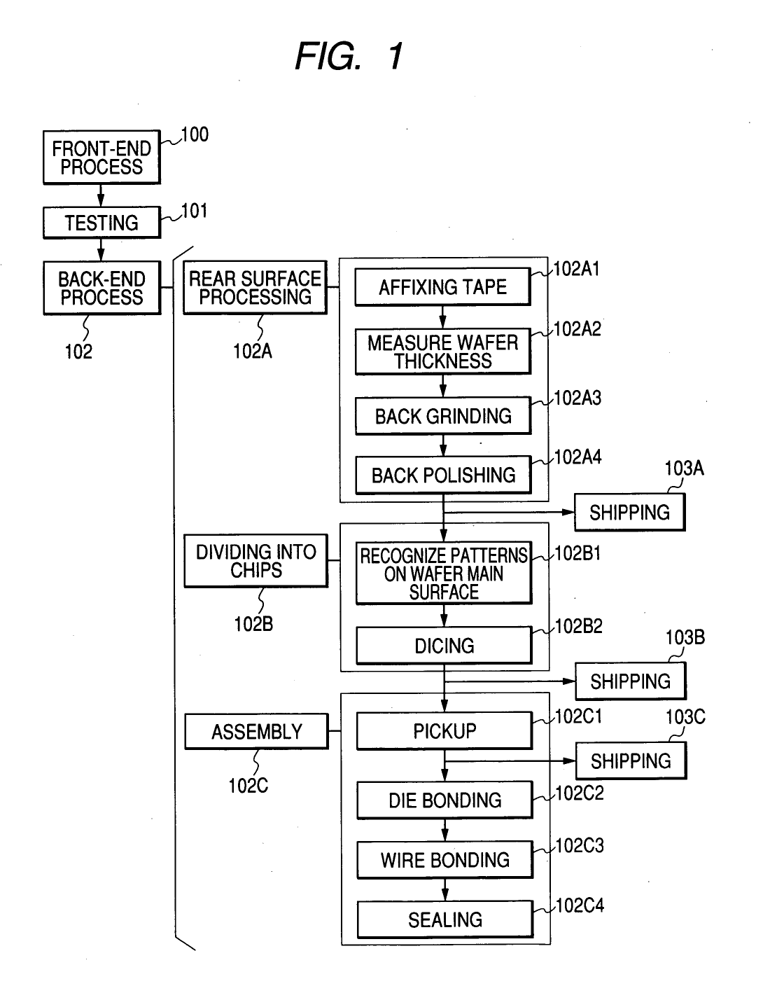

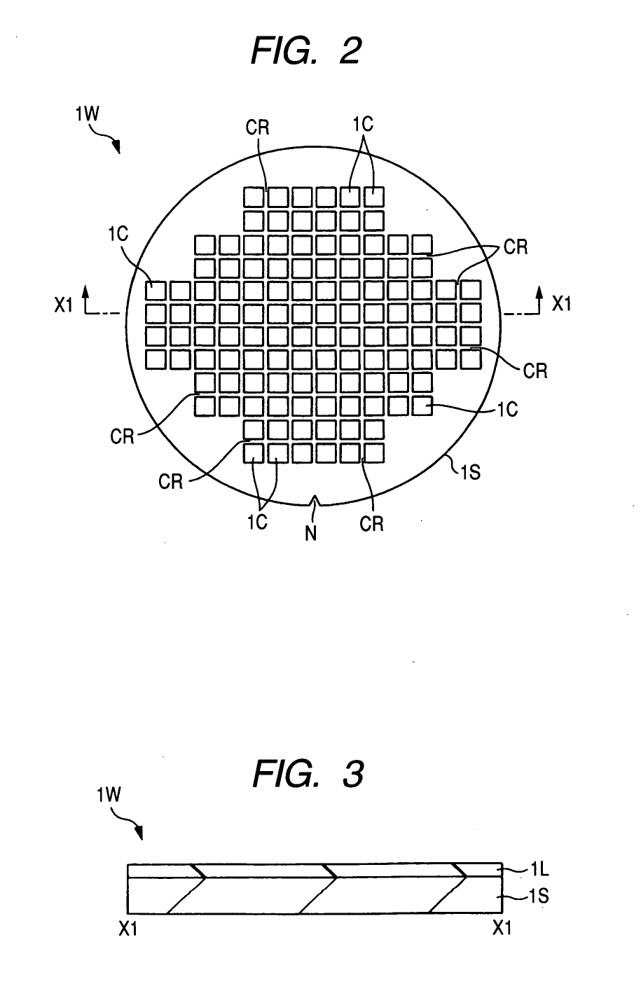

A semiconductor device manufacturing process according to a first embodiment of the present invention will be described below on the basis of the flow chart of FIG. 1 and with reference to FIGS. 2 to 28.

First, in a front-end process 100, a semiconductor wafer (hereinafter referred to simply as a “wafer”) having a substantially circular plane shape and a diameter of 300 mm or so, for example, is provided, and plural semiconductor chips (simply “chips” hereinafter) are formed on a main surface of the wafer. The front-end process 100 is also called a wafer process, diffusion process, or wafer fabrication, in which chips (elements and circuits) are formed on the main surface of the wafer and preparations are made so as to permit electric tests to be performed using probes or the like. The front-end process comprises a film forming process, an impurity introducing (diffusion or ion implantation) process, a photolithography process, an etching process, a metallizing process, and a process-to-process inspection process.

FIG. 2 is an overall plan view of a main surface of a wafer 1W and FIG. 3 is a sectional view taken on line X1-X1 in FIG. 2. Plural chips 1C having, for example, a square shape, as seen in plan views are arranged on the main surface of the wafer 1W through cutting regions CR formed around the chips. A semiconductor substrate (simply referred to as a “substrate” hereinafter) 1S of the wafer 1W is made of silicon (Si) single crystal, for example, and elements and a wiring layer 1L are formed on a main surface of the semiconductor substrate 1S. The thickness (the sum of the thickness of the substrate 1S and that of the wiring layer 1L) of the wafer 1W at this stage is about 775 μm, for example. The reference mark N denotes a notch.

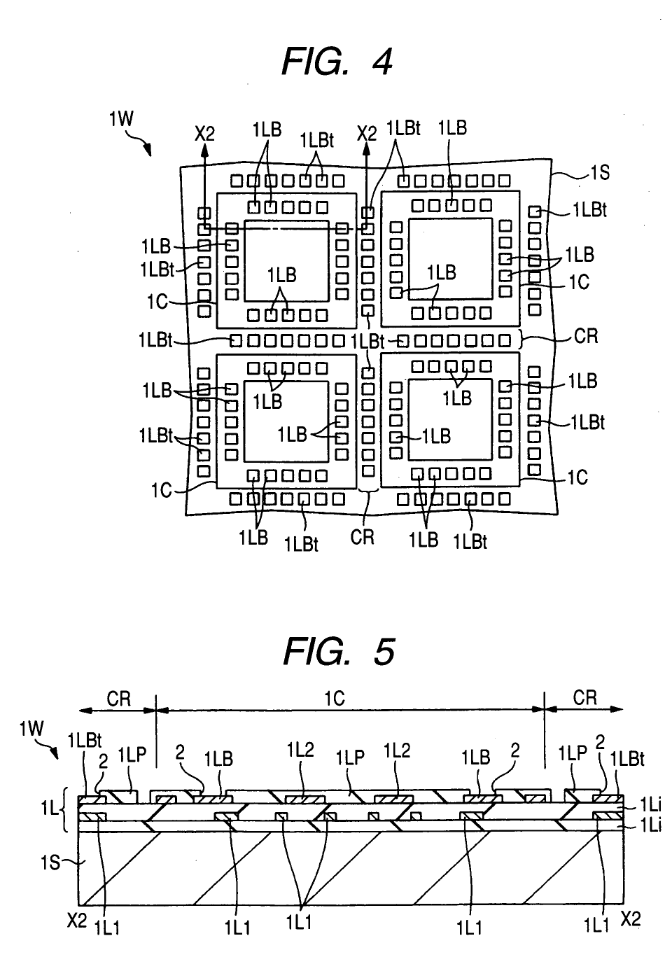

FIG. 4 is an enlarged plan view of a principal portion of an example of the wafer 1W shown in FIG. 2, and FIG. 5 is a sectional view taken on line X2-X2. In the wiring layer 1L, there are an inter-layer insulating film 1Li, wirings 1L1 and 1L2, bonding pads (external terminals, simply referred to as “pads” hereinafter) 1LB, testing pads 1LBt and a protective film 1LP. The inter-layer insulating film 1Li is in the form of an inorganic insulating film, such as, for example, a silicon oxide (e.g., SiO₂) film. The wirings 1L1, 1L2 and the pads 1LB, 1LBt are each formed by a metallic film, such as, for example, an aluminum film. The protective film 1LP, which covers the top wiring 1L2 and pads 1LB and 1LBt, is formed as a laminate film of both an inorganic insulating film, such as, for example, a silicon oxide film, and an organic insulating film, such as, for example, a polyimide resin film. The organic insulating film in the protective film 1LP is deposited in an exposed state on the top surface on the main surface side of the wafer 1W. Apertures 2 are formed in part of the protective film 1LP, and the pads 1LB and 1LBt are partially exposed from the apertures. The pads 1LB are arranged side by side along the outer periphery of each chip 1C. The testing pads 1LBt are arranged in the cutting regions CR of the chip 1C.

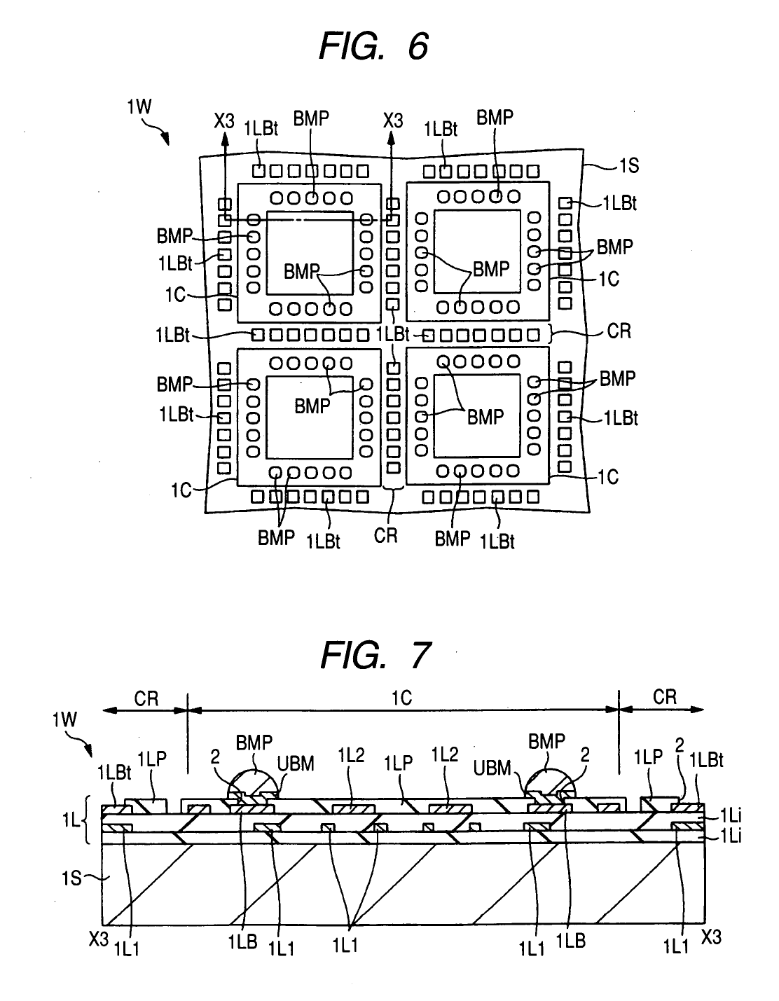

FIG. 6 is an enlarged plan view of a principal portion of another example of the wafer 1W shown in FIG. 2, and FIG. 7 is a sectional view taken along line X3-X3 in FIG. 6. In this example, bump electrodes BMP are formed on the pads 1LB through base metal UBM. The bump electrodes BMP are formed of a solder material, such as, for example, lead (Pb)-tin (Sn) or gold (Au), or they may be formed of a lead-free (Sn—Ag(silver)—Cu(copper)) solder material.

Next, in the testing step 101 shown in FIG. 1, various electrical characteristic tests are performed while applying probes to the pads 1LB of each chip 1C on the wafer 1W and also to the testing pads 1LBt in the cutting regions CR. This testing process is also called a G/W (Good chip/Wafer) check process, in which it is determined whether each chip 1C formed on the wafer 1W is good or bad electrically.

The subsequent process in FIG. 1, i.e., the back-end process 102, follows the above testing process 101. The back-end process 102 is a process up to the completion of sealing of each chip 1C within a sealing body (package).

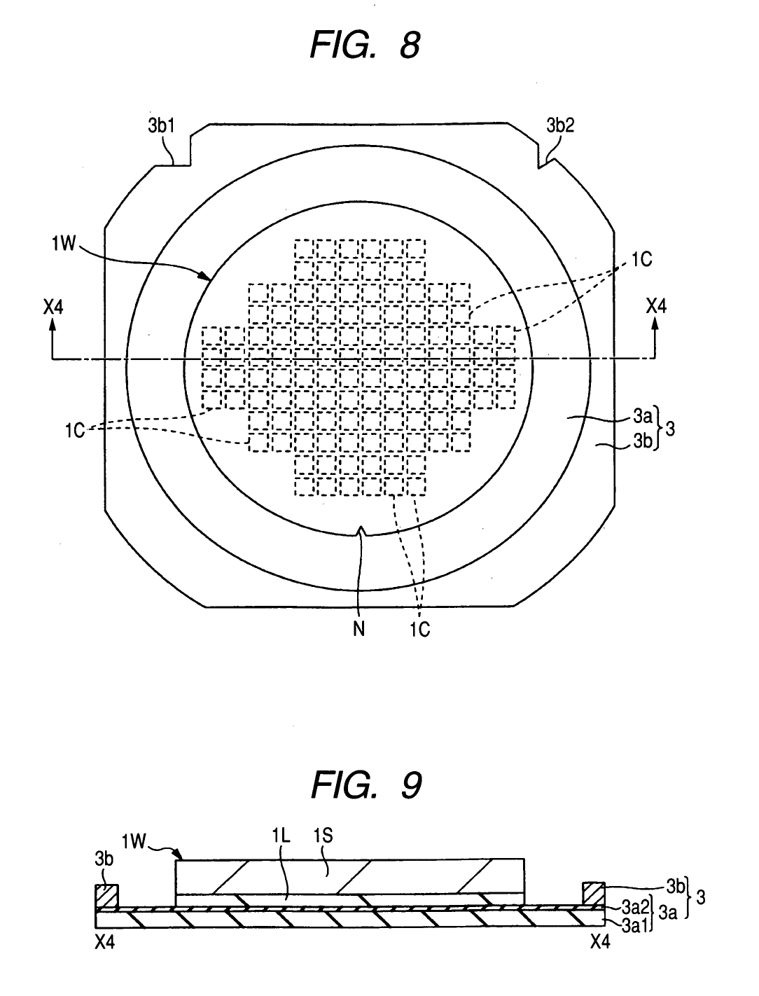

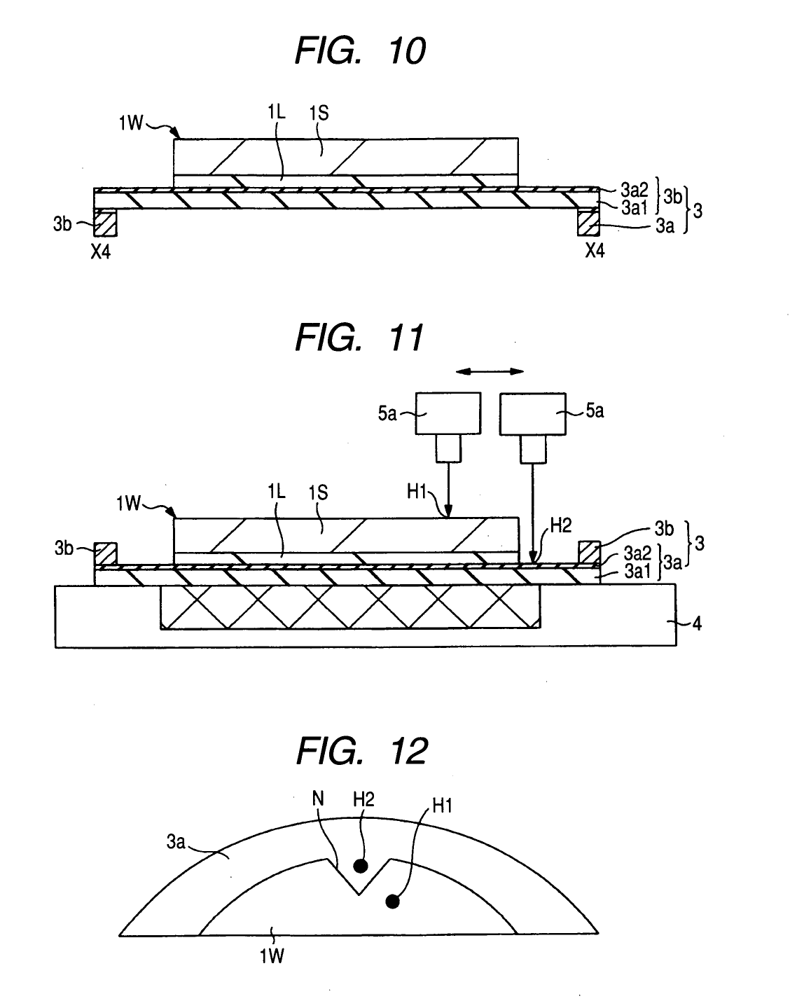

In a rear surface processing 102A, a tape is affixed to the main surface (chip-forming surface) of the wafer 1W (Step 102A1). FIG. 8 is an overall plan view of a jig 3 with the wafer 1W affixed thereto, FIG. 9 is a sectional view taken on line X4-X4 in FIG. 8, and FIG. 10 is a sectional view taken on line X4-X4 in FIG. 8 showing another example. In FIG. 8, how the chips IC are arranged on the main surface of the semiconductor wafer 1W is shown by broken lines. The jig 3 has a tape 3a and a ring (frame) 3b. The tape base 3a1 of the tape 3a is made of a flexible plastic material, for example, and an adhesive layer 3a2 is formed on a main surface of the tape base 3a1. The tape 3a is affixed firmly to the main surface of the wafer 1W through the adhesive layer 3a2. If the thickness of the tape 3a (the sum of the thickness of the tape base 3a1 and the thickness of the adhesive layer 3a2) is too large, it becomes difficult to effect handling and peeling of the tape 3a in subsequent steps of the manufacture. As the tape 3a, therefore, a tape which as thin as, for example, 130 to 210 μm is used. The use of a UV tape is a preferred example of the tape 3a. The UV tape is a pressure-sensitive adhesive tape using an ultraviolet (UV) curable resin as the material of the adhesive layer 3a. The UV tape has a strong adhesive force and possesses a property such that the adhesive force of the adhesive layer 3a2 weakens rapidly upon radiation of ultraviolet light thereon.

In this first embodiment, a ring 3b having a given rigidity is affixed to the outer periphery of the tape 3a. The ring 3b is a reinforcing member which functions to support the tape 3a for preventing deflection of the tape. From the standpoint of reinforcement, it is preferable that the ring 3b be formed of a metal, such as stainless steel, for example. But the ring 3b may be formed using a plastic material whose thickness is set so as to have about the same degree of hardness as metal. Cutout portions 3b1 and 3b2 are formed in the outer periphery of the ring 3b. The cutout portions 3b1 and 3b2 are not only used at the time of handling the jig 3, or at the time of alignment between the jig 3 and a manufacturing apparatus which carries the jig thereon, but it is also used as engaging portions at the time of fixing the jig 3 to the manufacturing apparatus. In this first embodiment, the jig 3 is used also at the time of dicing, as will be described later, and, therefore, the dimensions and shapes of various portions (including the cutout portions 3b1 and 3b2) of the jig 3 are set so as to be used in common to both rear surface processing and dicing.

FIG. 9 shows a case where the ring 3b is affixed to a main surface (wafer-affixed surface) of the tape 3a, while FIG. 10 shows a case where the ring 3b is affixed to a back surface (the surface opposite to the wafer-affixed surface) of the tape 3a. As shown in FIG. 9, in the case where the ring 3b is affixed to the main surface of the tape 3a, only a one-side adhesive layer (the adhesive layer 3a2 on the main surface of the tape 3a) need be used as an adhesive layer for affixing the ring 3b. It is optional whether the ring 3b is to be affixed to the tape 3a before affixing the wafer 1W to the tape or whether it is to be affixed to the tape 3a after affixing the wafer 1W to the tape.

Next, the ring 3b is affixed to the tape 3a to improve the support strength, and the thickness of the wafer 1W is measured in this state (Step 102A2). FIG. 11 is a sectional view showing an example of the step of measuring the thickness of the wafer 1W, and FIG. 12 is an enlarged plan view of a principal portion in the thickness measurement for the wafer 1W shown in FIG. 11. In this step, the jig 3 which holds the wafer 1W is placed on a vacuum chuck stage 4 in a rear surface processing apparatus and is fixed by vacuum suction. In this state, the height H1 of a back surface of the wafer 1W and the height H2 of the tape 3a are measured using an infrared camera (“IR camera” hereinafter) 5a, whereby the actual thickness of the wafer 1W and variations (about ±7-8 μm) in thickness of the tape 3a can be measured, and with this it is possible to determine the exact quantities needed for grinding and polishing.

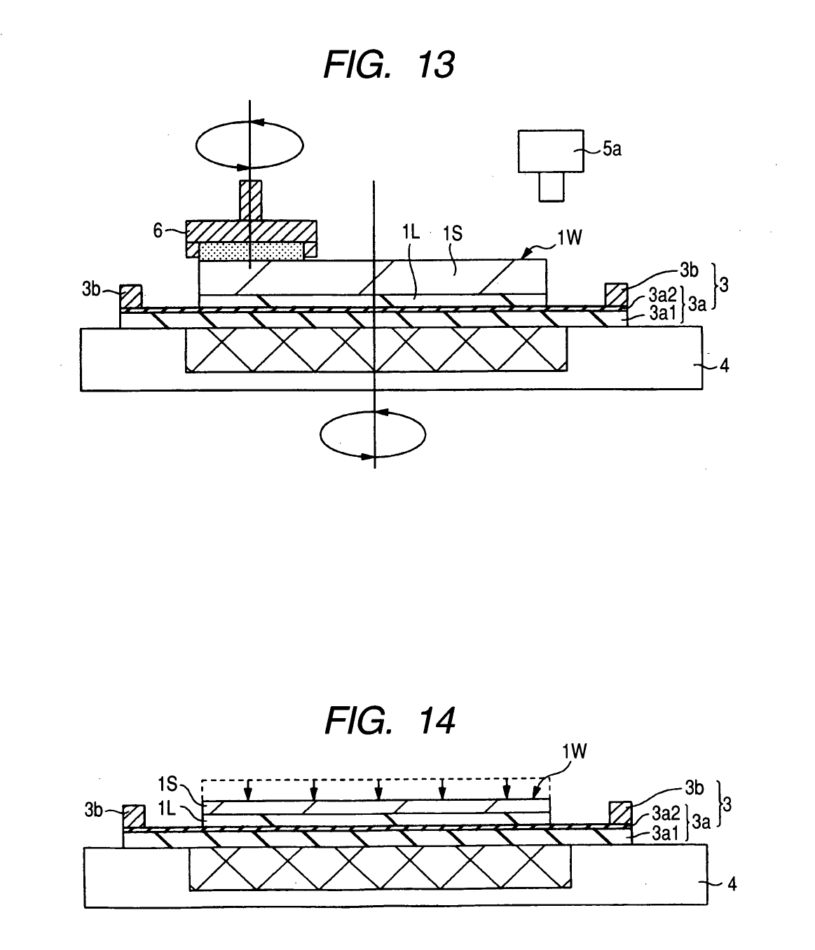

Thereafter, as shown in FIG. 13, a grinding/polishing tool 6 and the vacuum chuck stage 4 are rotated and the back surface of the wafer 1W is subjected to grinding and polishing in this order on the basis of the above-determined grinding and polishing quantities (Steps 102A3 and 102A4), whereby, as shown in FIG. 14, the thickness of the wafer 1W is made extremely small, e.g., 100 μm or less (here 90 μm or so). As the chip thickness becomes as small as 100 μm or less, the deflective strength of each chip decreases due to damage or stress induced on the back surface of the wafer 1W by the grinding work, with the result that the chip is apt to be cracked by pressure developed when mounting the chip. Thus, the grinding process is important in eliminating the damage and stress on the back surface of the wafer 1W lest such inconvenience should occur. For the polishing process one may use not only a method wherein polishing is performed using a polishing pad and silica or a chemical mechanical polishing (CMP) method, but also an etching method using, for example, nitric acid and hydrofluoric acid.

After completion of the rear surface processing described above, the state of vacuum suction of the vacuum chuck stage 4 is released and the jig 3 which holds an extremely thin wafer 1W is taken out from the rear surface processing apparatus. At this time, according to this first embodiment, the tape 3a can be supported firmly by the ring 3b even if the wafer 1W is extremely thin, so that it is possible to facilitate handling and conveyance of the extremely thin wafer 1W. Besides, it is possible to prevent the wafer 1W from being cracked or warped during handling or conveyance. Consequently, it is possible to ensure the quality of the wafer 1W. In this first embodiment, therefore, after the rear surface processing, the extremely thin wafer 1W may be shipped to another manufacturing factory (e.g., assembly fab) while being held by the jig 3 so as to be subjected therein to dicing and assembly after the rear surface processing (Step 103A).

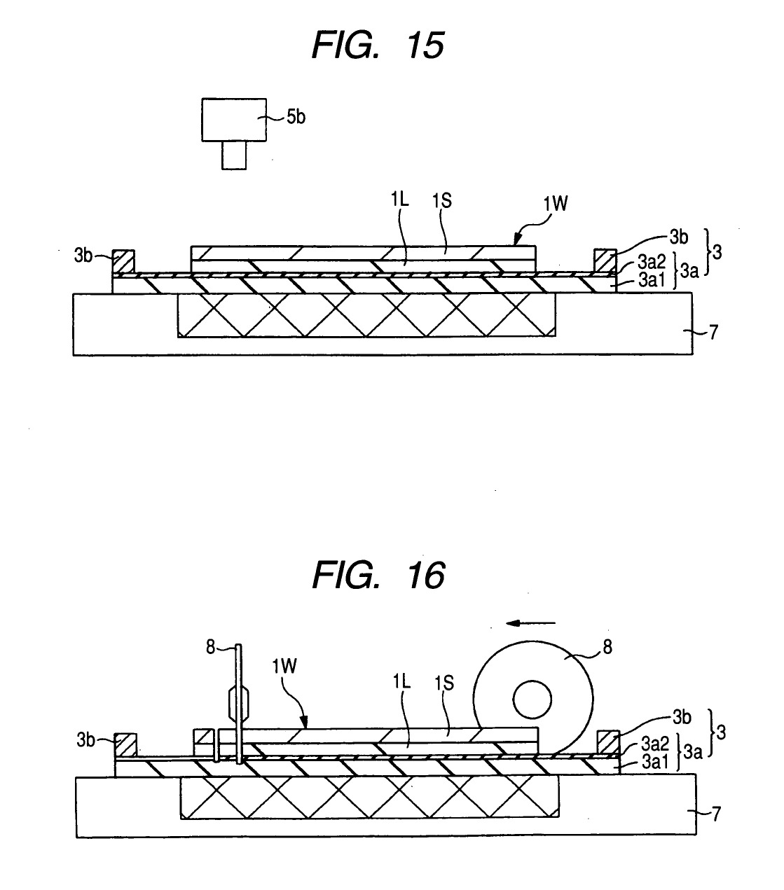

Next, a shift is made in the process to a dividing step 102B for dividing the wafer into individual chips. In this step, first the jig 3, which holds the extremely thin wafer 1W, is conveyed to a dicing apparatus and is placed on a vacuum chuck stage 7 in the dicing apparatus, as shown in FIG. 15. That is, it is usually necessary to go through a step (wafer mounting step) of peeling the tape affixed to the main surface of the wafer 1W after the rear surface processing and affixing a dicing tape to the back surface of the wafer 1W, but in this first embodiment, the wafer mounting step can be omitted, and, hence, it is possible to simplify the semiconductor device manufacturing process. Consequently, it is possible to shorten the time required for manufacturing the semiconductor device. Moreover, since it is possible to eliminate the need for using a dicing tape, it is possible to reduce the material cost and the cost of the semiconductor device.

Subsequently, for dicing the wafer 1W with the tape 3a affixed to the wafer main surface in this first embodiment, patterns (patterns of chips 1C and cutting regions CR) formed on the main surface of the wafer 1W are recognized from the back surface side of the wafer by means of an IR camera 5b, while the jig 3 is held in a vacuum-sucked state (Step 102B1). At this time, in this first embodiment, the state of the patterns on the main surface of the wafer 1W can be fully observed because the wafer is extremely thin. Thereafter, alignment (positional correction) of dicing lines (cutting regions CR) is performed on the basis of the pattern information obtained by the IR camera 5b, and dicing is carried out (Step 102B2). For the dicing, a blade dicing method or a stealth dicing method may be adopted.

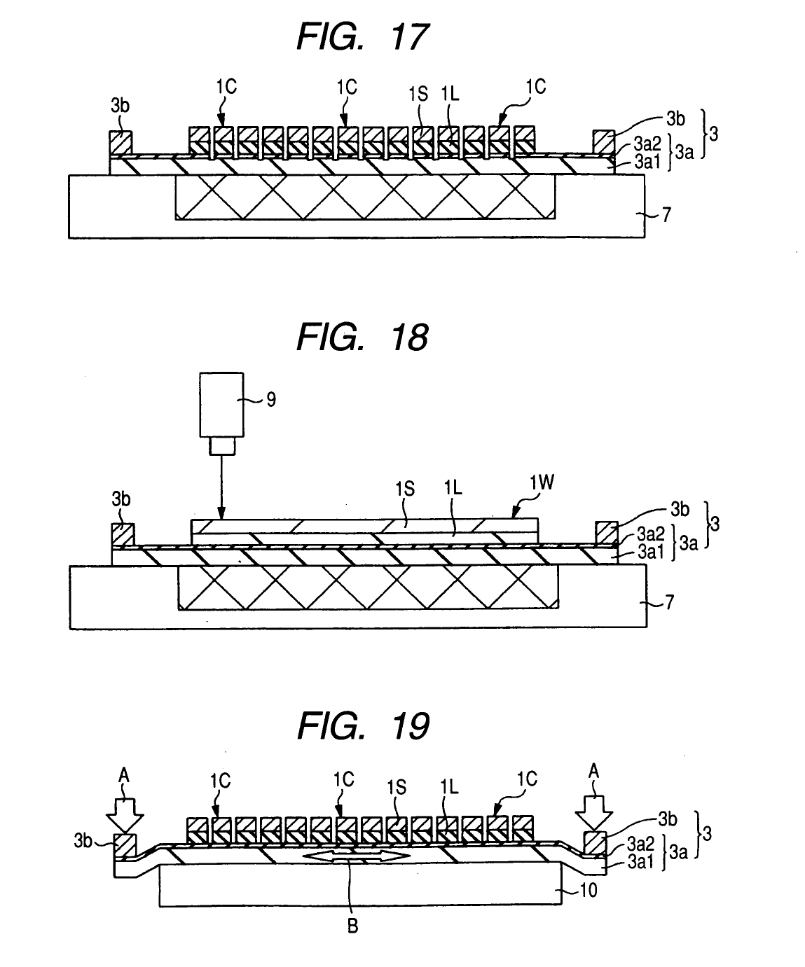

FIGS. 16 and 17 show a case in which the blade dicing method is adopted. As shown in FIG. 16, a dicing blade (cutting edge) 8, which is rotating at high speed, is pushed against the cutting regions CR from the back surface side of the wafer 1W so as to cut the wafer 1W into individual chips 1C, as shown in FIG. 17.

FIGS. 18 and 19 show a case in which the stealth dicing method is adopted. As shown in FIG. 18, a laser beam emitted from a laser beam generator 9 is radiated along the cutting regions CR from the back surface side of the wafer 1W to form a modified layer in the interior of the wafer. Thereafter, as shown in FIG. 19, with the jig 3 placed on a table 10, the ring 3b is pushed down in the direction of the arrow A to stretch the tape 3a along the direction of arrow B. In this way the wafer 1W is cut into individual chips by a relatively small force using the above-mentioned modified layer as a base point. As an example of the laser beam, there is an NIR (near infrared) laser beam having a transparent wavelength relative to the wafer 1W. In the case of the foregoing blade dicing method, the thinner the wafer 1W, the more likely will be the occurrence of chipping during the cutting work and the lower will be the deflective strength of each chip. Therefore, from the standpoint of ensuring the quality of the chips 1C, a low-speed processing is inevitable (e.g., 60 mm or so per second or lower, depending on the thickness of the wafer 1W). On the other hand, in using the stealth dicing method, it is possible to minimize chipping on the chip surface, because only the interior of the wafer 1W is diced, without doing damage to the wafer surface. Consequently, it is possible to improve the deflective strength of each chip 1C. Moreover, since the cutting work can be done at a high speed, such as 300 mm per second, for example, it is possible to improve the throughput. As noted above, the testing pads 1LBt, through which infrared rays cannot pass, are present in the cutting regions CR on the main surface of the wafer 1W; therefore, if a laser beam is radiated from the main surface side of the wafer 1W, the testing pads 1LBt obstruct the beam radiation, and processing (forming a modified layer) of those portions may not be carried out to a satisfactory extent. On the other hand, in this first embodiment, since a laser beam is radiated from the back surface side of the wafer 1W, where metal elements such as the testing pads 1LBt are not present, a modified layer can be formed in a satisfactory manner without the occurrence of the aforesaid inconvenience, and it is possible to cut the wafer 1W in a satisfactory manner.

In this first embodiment, a plurality of extremely thin chips 1C, resulting after the dicing step described above, may be shipped to another manufacturing factory (e.g., assembly fab), while being held by the jig 3, and they may be subjected to assembly, which follows the dicing step (Step 103B).

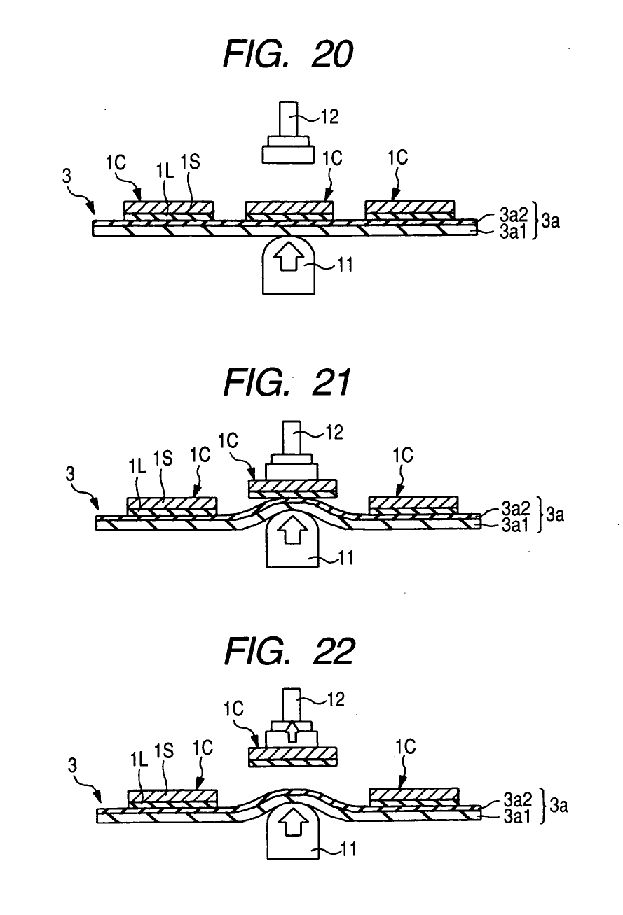

Next, a shift is made in the processing to an assembling step 102C. In this step, the jig 3 which holds plural chips 1C is conveyed to a pickup device. FIG. 20 is an enlarged sectional view of a principal portion of the jig 3 placed on the pickup device. A push-up pin 11 is installed on the back surface side of the tape 3a so as to be movable vertically. Further, a collet 12 is installed above the back surfaces of the chips 1C so as to be movable vertically and transversely. Although a flat collet is used as the collet 12, an inverted pyramidal collet may be used as well. In this pickup step, as shown in FIG. 21, the back surface of the tape 3a is vacuum-chucked; and, in this state, the chip 1C is pushed up from the back surface side of the tape 3a by means of the push-up pin 11. At this time, in case of using the foregoing UV tape as the tape 3a, ultraviolet light is radiated to the adhesive layer 3a2 of the tape 3a to cure the adhesive layer 3a2, thereby weakening the adhesive force. In this state, the semiconductor chip 1C is vacuum-chucked by the collet 12, whereby the chip 1C is picked up, as shown in FIG. 22 (Step 102C1).

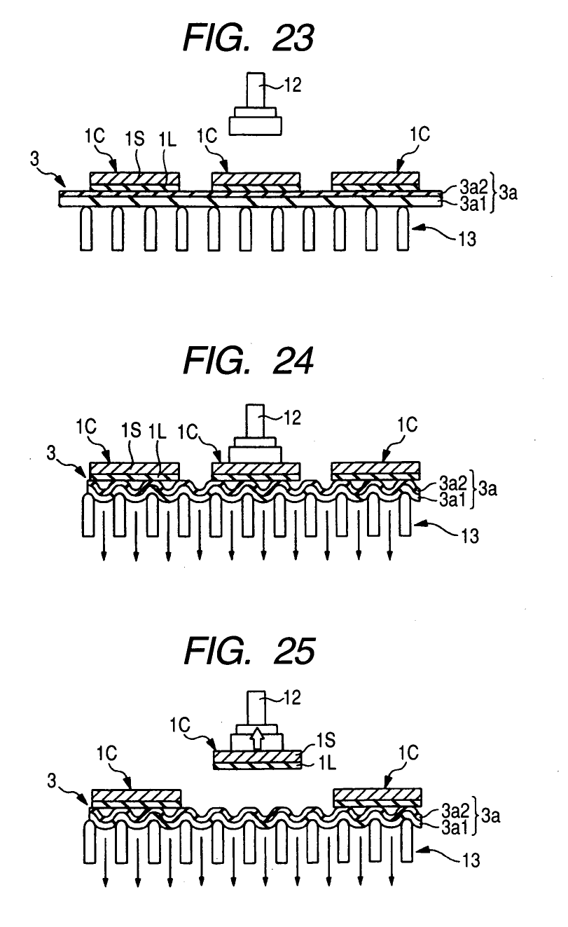

However, when the chip 1C is thin, cracking of the chip or a pickup error may occur in response to the pushing force of the push-up pin 11, even if the UV tape is used. In such a case, the following measure may be adopted. FIG. 23 is an enlarged sectional view of a principal portion of the jig 3 placed on the pickup device. In the same figure, a multi-lug chuck element 13 is installed on the back surface side of the tape 3a. In this case, as shown in FIG. 24, the tape 3a is vacuum-chucked from its back surface side through suction holes formed in the multi-lug chuck element 13, thereby changing the state of contact between the main surfaces of the chips 1C and the main surface of the tape 3a from a surface contact to a point contact. As a result, it is possible to decrease the area of contact between the chips 1C and the tape 3a. In this state, as shown in FIG. 25, a chip 1C is more easily picked up by the collet 12 (Step 102C1). In this way, even an extremely thin chip 1C can be picked up without cracking, etc. Although in this case the chip 1C can be picked up easily even without using UV tape as the tape 3a, the chip 1C can be picked up even more easily by using UV tape and radiating ultraviolet light to the adhesive layer 3a2 of the tape 3a when picking up the chip so as to weaken the adhesion.

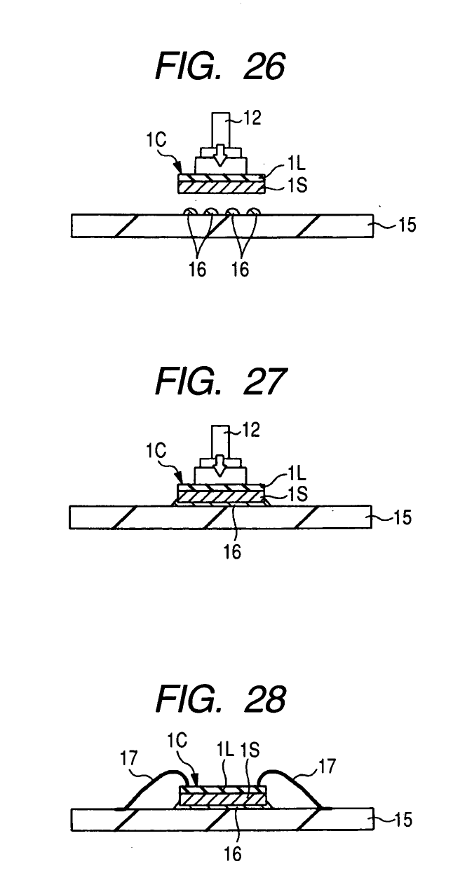

Subsequently, the chip 1C, thus picked up, is inverted by an existing inverting unit in such a manner that the main surface of the chip faces up. Thereafter, as shown in FIG. 26, the chip 1C is conveyed by the collet 12 up to a chip mounting area on a printed wiring board 15, for example. In the chip mounting area of the printed wiring board 15, an adhesive 16, such as, for example, silver (Ag) paste, is applied in a matrix-like dotted state. As the case may be, the printed wiring board 15 may be replaced by a lead frame. In this case, chips 1C are mounted onto die pads (chip mounting portions) of the lead frame. The chips 1C, after pickup, may be accommodated in a conveyance tray and shipped to another manufacturing factory (e.g., assembly fab) for subsequent assembly (Step 103C). As to the conveyance tray, a description will be given later.

Then, as shown in FIG. 27, each chip 1C is placed on the chip mounting area of the printed wiring board 15, while its back surface is allowed to face the chip mounting area, and then it is scrubbed in an appropriate direction and pushed moderately to spread the adhesive 16 throughout the whole of the back surface of the chip. Thereafter, the adhesive 16 is cured to fix the chip 1C onto the printed wiring board 15 (Step 102C2).

Next, as shown in FIG. 28, the pad 1LB on the main surface of the chip 1C and an electrode on the printed wiring board 15 are connected together through a bonding wire (simply referred to as a “wire” hereinafter) 17 (Step 102C3). Subsequently, the chip 1C is sealed with a sealing body consisting of a plastic material, such as, for example, epoxy resin, in accordance with a transfer molding method (Step 102C4). In the case where the chip 1C has bump electrodes BMP, as shown in FIGS. 6 and 7, the chip 1C is conveyed in the pickup step 102C1 to the chip mounting area of the printed wiring board 15 in a state in which the main surface of the chip faces down, and then the bump electrodes BMP of the chip 1C and electrodes in the chip mounting area are fixed together temporarily with use of paste, followed by a reflow process (heat-curing) to fix the bump electrodes BMP of the chip 1C and the electrodes of the printed wiring board 15 to each other (flip-chip bonding). Thereafter, underfill resin is injected between opposed surfaces of the chip 1C and the printed wiring board 15, and then the chip 1C is sealed in the same way as indicated above (Step 104C4).

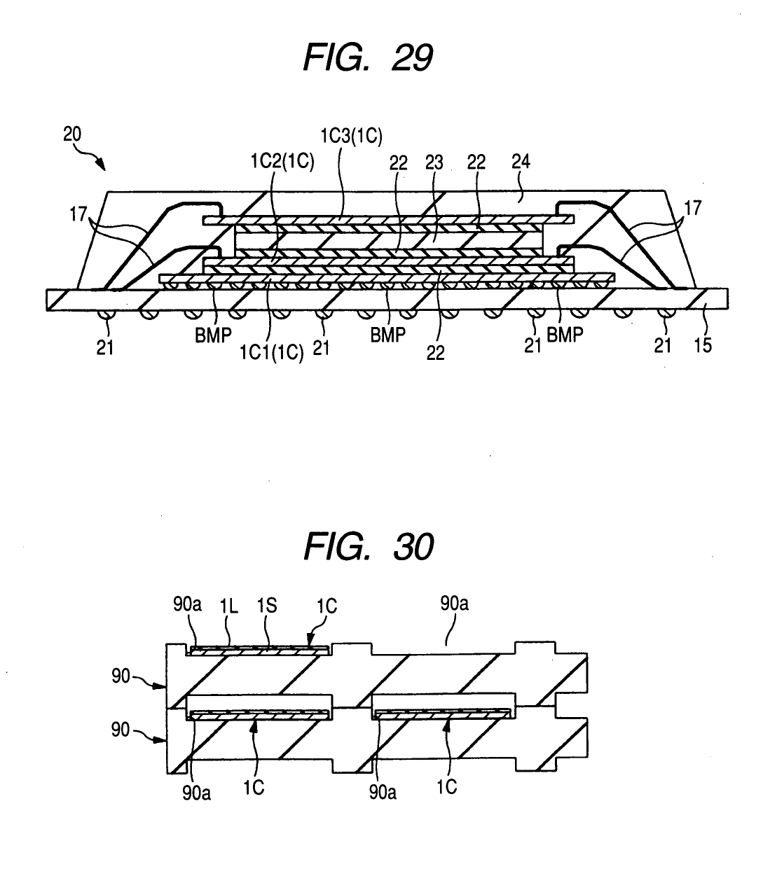

FIG. 29 shows an example of a sectional view of a semiconductor device 20 that has been manufactured by the semiconductor device manufacturing method of the first embodiment. The semiconductor device 20 has an SIP (System In Package) configuration wherein a system having a desired function is built within one package. Plural bump electrodes 21 are arranged in a matrix shape on a back surface of a printed wiring board 15, which constitutes the semiconductor device 20. Further, plural thin chips 1C1 to 1C3 (1C) are stacked on a main surface of the printed wiring substrate 15. The bottom layer chip 1C1 is mounted on the main surface of the printed wiring board 15 through bump electrodes BMP formed on a main surface thereof. A logic circuit, such as, for example, a CPU (Central Processing Unit) or DSP (Digital Signal Processor), is formed on the main surface of the chip 1C1. On a back surface of the chip 1C1, a chip 1C2 is mounted through a die attach film 22. On a main surface of the chip IC2, a memory circuit, such as, for example, a SRAM (Static Random Access Memory) or a flash memory, is formed. Pads 1LB formed on the main surface of the chip 1C2 are electrically connected through wires 17 to electrodes formed on the main surface of the printed wiring board 15. A chip 1C3 is mounted on the main surface of the chip 1C2 through a spacer 23 and a die attaching film 22. A memory circuit, such as, for example, a SRAM or a flash memory, is formed on the chip 1C3, and pads 1LB formed on a main surface of the chip 1C3 are electrically connected through wires 17 to electrodes formed on the main surface of the printed wiring board 15. The chips 1C1 to 1C3 and the wires 17 are sealed with a sealing body 24 of epoxy resin, for example.

According to the semiconductor device manufacturing method of the first embodiment, as described above, chips can be stacked in multiple stages, like the chips 1C1 to 1C3 shown in FIG. 29, and thus, it is possible to reduce the thickness of the semiconductor device 20 having a SIP configuration. Moreover, the reliability of the semiconductor device 20 having a SIP configuration can be improved.

Although, in the first embodiment, the ring 3b is affixed to the tape 3a before the thickness measurement, this does not always constitute a limitation so long as the affixing of the ring 3b to the tape 3a is completed before the back grinding step.

### Second Embodiment

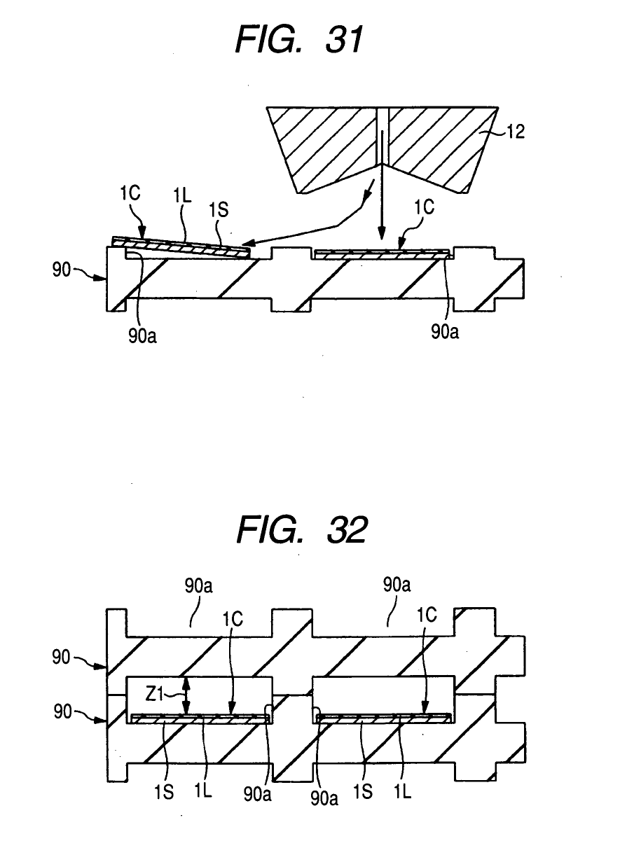

In connection with this second embodiment, a description will be given concerning a conveyance tray for thin chips. FIG. 30 is a sectional view of a principal portion of an ordinary type of conveyance tray 90. With a decrease in thickness of chips 1C, pockets 90a formed in the conveyance tray 90 are also becoming shallower, while taking product protectiveness into account. However, if the pockets 90a are too shallow, when a chip 1C is accommodated into or removed from a pocket 90a, this chip accommodating or removing work affects other chips 1C already received in adjacent pockets 90a, thus giving rise to the problem that the other chips 1C move out of the pockets 90a. FIG. 31 shows an example of this state, in which a chip 1C is about to be received in a pocket 90a. Usually, for accommodating a chip 1C into a pocket 90a formed in the conveyance tray 90, the chip 1C is vacuum-chucked by the collet (an inverted pyramidal collet is illustrated) and, in this state, is conveyed to a position of a desired pocket 90a in the conveyance tray 90, and then the vacuum suction of the collet 12 is released, causing the chip 1C to drop into the desired pocket 90a. However, when the chip is as thin as about 100 μm or less, the chip 1C may not separate or is difficult to separate from the collet 12 by only release of the vacuum suction of the collet, not only due to a light weight of the chip 1C, but also due to the cupule effect, electrostatic action, or the adhesion of polyimide resin on the main surface of the chip 1C. In such a case, the chip 1C may not be deposited into the pocket 90a properly. To solve this problem, when accommodating the chip 1C into the pocket 90a, air is reverse-injected, as indicated by the arrow in FIG. 31, to separate the chip 1C from the collet 12 and accommodate it into the desired pocket 90a. However, since the pockets 90a in the conveyance tray 90 are shallow and the chips 1C are thin and light, there arises the problem that the chip 1C already accommodated in an adjacent pocket 90a moves out of the pocket under the influence of the air flow from the collet 12. This problem may be solved by making the pockets 90a deep with respect to the thickness of each chip 1C. By so doing, the problem involved in taking each chip 1C in and out is solved. However, if the pockets 90a are simply made deep, when chips 1C are accommodated in the conveyance tray 90, the distance Z1 from the main surface of each chip 1C to a back surface (ceiling surface) of the conveyance tray 90 opposed to the chip main surface becomes longer, with the result that the chips 1C accommodated in the conveyance tray 90 are apt to move vertically or rotate during conveyance, giving rise to problems, such as the chips 1C being scratched or chipped or a part of the inner wall surfaces of the conveyance tray 90 being shaved by movement of chips 1C with consequent formation of foreign matter.

In this second embodiment, therefore, reference will be made below to a conveyance tray which, at the time of accommodating or removing a thin chip 1C to or from the conveyance tray (simply referred to as a “tray” hereinafter), can prevent adjacent chips 1C from being affected and which, during conveyance of chips 1C, can prevent vertical movement and rotation of the chips. The conveyance includes conveyances for various purposes, such as process-to-process conveyance and conveyance for shipping.

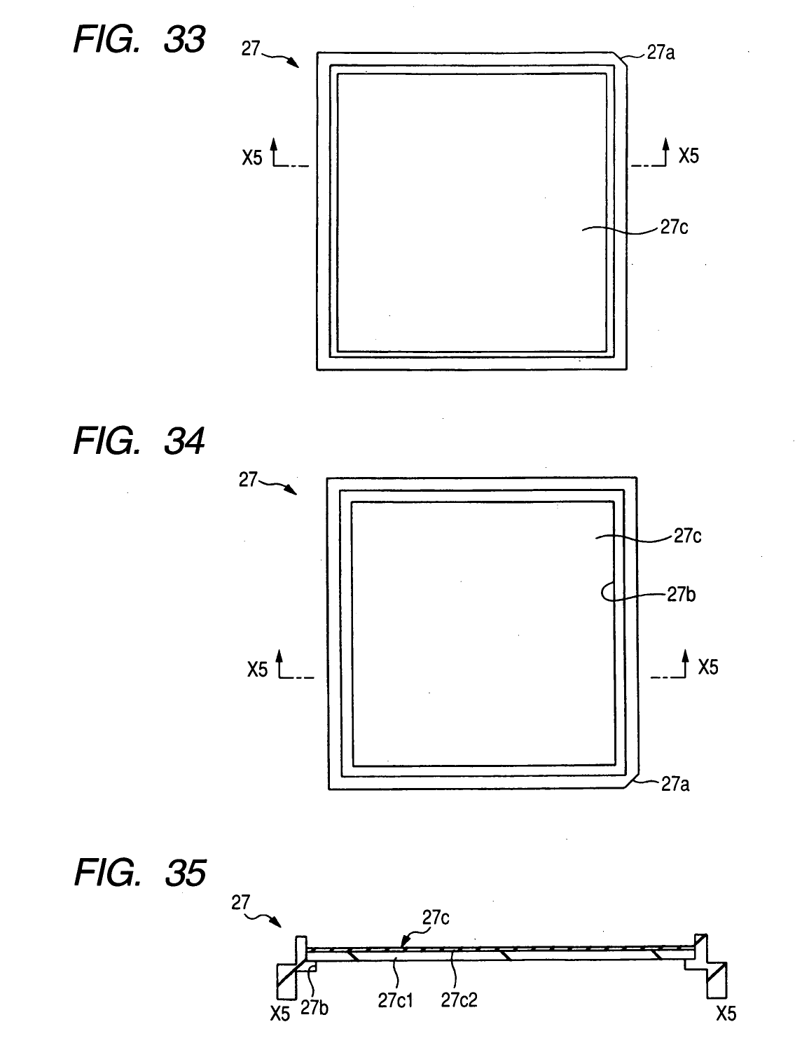

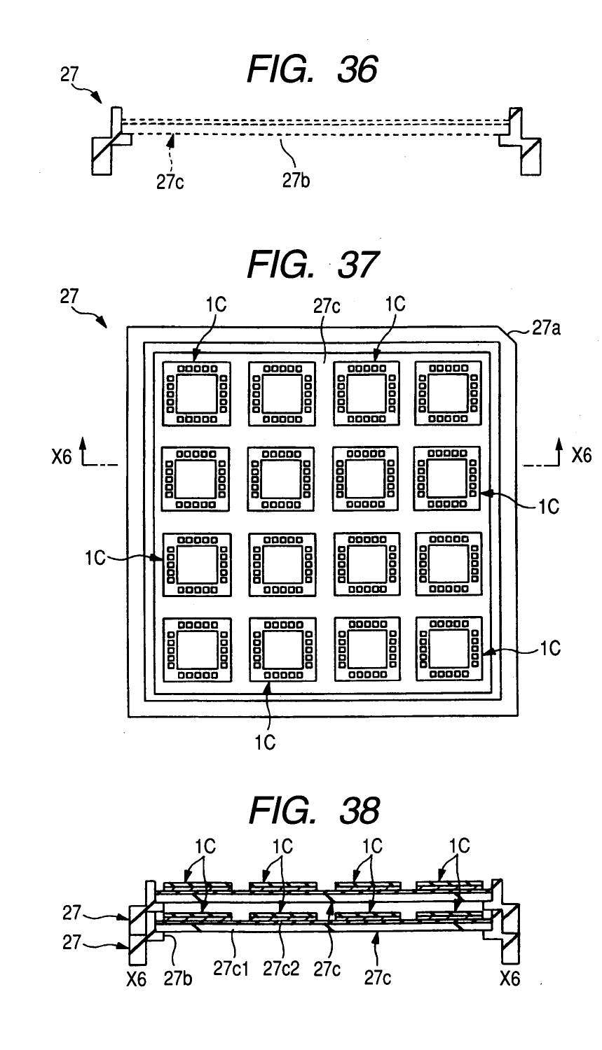

FIG. 33 is an overall plan view of a main surface of a tray 27 according to this second embodiment, FIG. 34 is an overall plan view of a back surface of the tray 27, FIG. 35 is a sectional view taken on line X5-X5 in FIGS. 33 and 34, and FIG. 36 is a sectional view of the tray 27 shown in FIGS. 33 to 35 with the tape removed.

The tray 27 according to this second embodiment is a tray used for the conveyance of thin chips 1C. For example, the tray 27 is in the shape of a generally square thin plate, as seen in plan view, with a chamfered portion 27a for an index being formed at one corner. Its profile dimensions are, for example, about 50 mm long, about 50 mm wide, and about 4 mm high. The tray 27 is formed of an insulating material, such as, for example, AAS (acrylonitrile-acrylate-styrene) resin, ABS (acrylonitrile-butadiene-styrene) resin, or PS (polystyrene) resin. From the standpoint of diminishing the charging of static electricity and thereby suppressing or preventing electrostatic breakdown of the chips, for example, a hydrophilic polymer is contained in the tray 27. As a measure against electrostatic breakdown, carbon may be added to the tray 27 or conductor patterns may be formed on the tray. However, the addition of a hydrophilic polymer can decrease the formation of foreign matter in comparison with the addition of carbon, and this technique permits easier formation thereof than forming conductor patterns, thus making it possible to reduce the cost of the tray 27. An opening 27b is formed centrally of both the main surface and back surface of the tray 27 so as to pass through both the main and back surfaces, and a tape 27c is affixed to the tray so as to close the opening 27b. The tape 27c has a tape base 27c1 and an adhesive layer 27c2 formed on a main surface thereof.

FIG. 37 is an overall plan view of the main surface of the tray 27 with chips 1C accommodated therein in two stages, and FIG. 38 is a sectional view taken on line X6-X6 in FIG. 37.

In the illustrated example, the chamfered portions 27a for index of two trays 27 are aligned with each other, and concave portions formed on the back surface of the upper tray 27 are fitted on convex portions formed on the main surface of the lower tray 27, whereby both trays 27 can be stacked stably in their thickness direction.

For example, 4×4 chips 1C are affixed to the main surface of the tape 27c in each tray 27 through the adhesive 27c2. That is, the chips 1C are mounted in such a manner that their main surfaces (the surface on which elements and wirings are formed) are opposed to the back surface of the upper tray 27, and their back surfaces are in contact with the main surface of the tape 27c in the lower tray 27. Thus, when a chip 1C is accommodated or removed with respect to the tray 27, this work does not exert any bad influence on the other chips 1C that have already been received in the tray. Moreover, during the conveyance of chips 1C, there is no fear of vertical or transverse movement or rotation of the chips, because the chips are affixed and thereby fixed to the tape 27c. Thus, there is no fear of occurrence of chipping or the like, nor is there any fear of the tray 27 being shaved by movement of the chips 1C, which would cause the formation of foreign matter. Consequently, it is possible to ensure the quality of the chips 1C.

For example, the tape 27c is a UV tape. When picking up a chip 1C from the tray 27, ultraviolet light is radiated to the adhesive layer 27c2 of the tape 27c to weaken the adhesion of the adhesive layer 27c2, whereby removing the chip 1C from the tray 27 can be done easily. The tape 3a used in the foregoing rear surface processing or dicing is required to have a strong adhesive force so as to withstand a mechanical stress induced in the rear surface processing or dicing. But in the case of the tape 27c of the tray 27, a lower adhesive force than that of the tape 3a suffices, so that a chip 1C, even if it is thin, can be picked up easily without cracking by decreasing the adhesive force in response to the radiation of ultraviolet light.

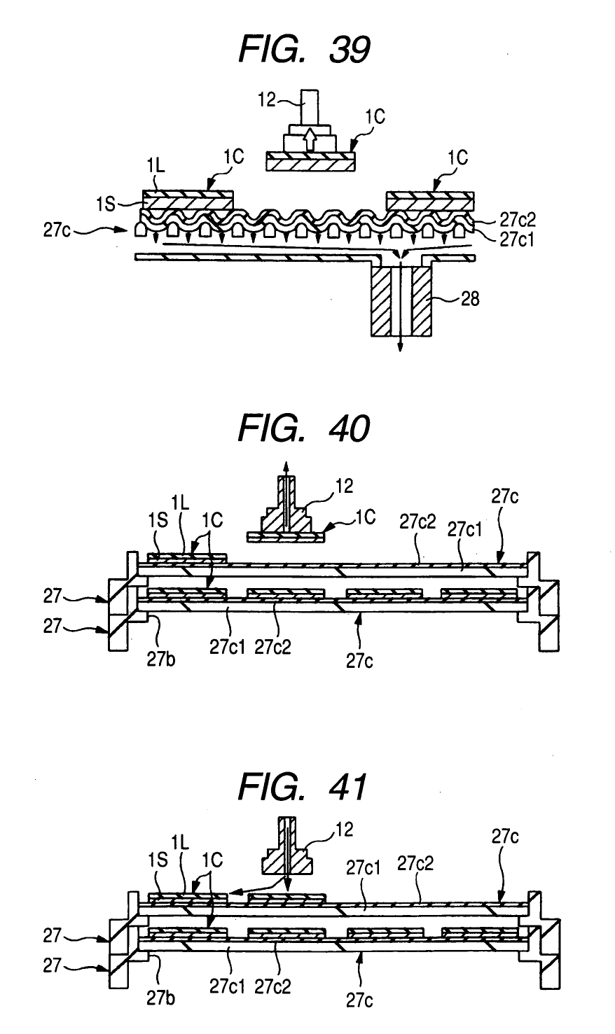

A construction such as shown in FIG. 39 may be adopted, in which, when the tape 27c is chucked by vacuum chuck means 28 from the back surface of the tape 27c, the state of contact between the back surface of the chip 1C and the main surface of the tape 27c changes from surface contact to point contact. According to this construction, the area of contact between the chip 1C and the tape 27c can be decreased, and, hence, the chip can be picked up more easily without cracking. In this case, the removal of the chip 1C can be done easily even without the use of UV tape, but by using a UV tape and by radiating ultraviolet light to the adhesive layer 27c2 of the tape 27c at the time of pickup, the removal of the chip 1C can be done more easily. As to assembly of the chip 1C after pickup, an explanation thereof will be omitted because it is the same as that of the first embodiment.

The tape 27c is provided in a removable state. By replacing the tape 27c after every conveyance, it is possible to eliminate the problem that foreign matter that has adhered to the tape 27c will adhere to a chip 1C. Thus, it is possible to ensure the quality of chips 1C during conveyance.

Further, by forming the tape 27c with use of a transparent material, the back surfaces of the chips 1C affixed to the tape 27c can be checked by observation through the tape 27c.

The following description is now provided concerning an example of a method for accommodating each chip 1C in the tray 27 in this second embodiment.

FIGS. 40 and 41 are sectional views of a principal portion of the tray 27 in the process of accommodating a chip 1C in the tray 27. First, as shown in FIG. 40, a chip 1C is vacuum-chucked by the collet 12, and, in this state, is conveyed to a desired position over the main surface of the tape 27c of the tray 27. In this case, the chip 1C is chucked in a state in which the main surface of the chip faces the vacuum chuck surface of the collet 12. Subsequently, the vacuum chuck condition of the collet 12 is released. As noted earlier, when the chip 1C is as thin as 100 μm or so, the chip 1C cannot be separated from the collet 12 by only release of the vacuum chuck condition, not only due to the light weight of the chip 1C, but also due to the cupule effect, electrostatic action, or the adhesive force of the polyimide resin film formed on the main surface side of the chip 1C. As a countermeasure, also in this second embodiment, air is lightly reverse-injected to the chip 1C side, as shown in FIG. 41, thereby placing the chip 1C in a desired position of the tape 27c and affixing it to the tape. At this time, in this second embodiment, since the other chips 1C already accommodated in the tray 27 are affixed and fixed to the tape 27c, it is possible to prevent movement of the other chips 1C even if an air flow that is reverse-injected from the collet 12 passes across the other chips that have already been accommodated in the tray.

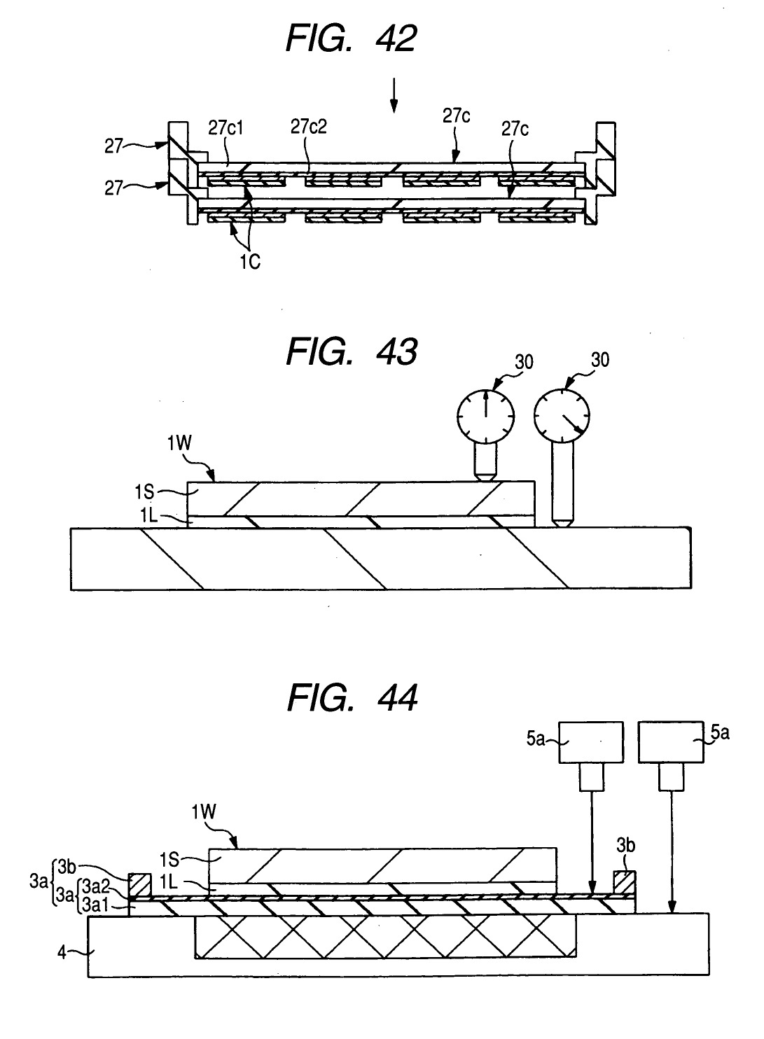

Next, the following description is provided concerning a method for checking the back surfaces of chips 1C during conveyance of the chips. FIG. 42 shows in what manner the back surfaces of chips 1C are checked. The tray 27 is inverted as shown in FIG. 42 from the state shown in FIG. 38, and the back surfaces of chips 1C are checked in the direction of the arrows. The chips 1C remain affixed to the tape 27c at this time. After completion of the check, the tray 27 is again inverted to its original state, as shown in FIG. 38. In the case of the tray 90 shown in FIG. 30, when the tray 90 is restored to its original state after checking the back surfaces of the chips, the chips 1C may remain affixed to the back surface (ceiling surface) of the upper tray 90, not only due to the chips 1C being thin and light, but also due to an electrostatic action and the adhesion of the polyimide resin on the main surface of each chip 1C. Therefore, when the upper tray 90 is removed in its original state, as mentioned above, at the stage of picking up a chip 1C from the tray, there arises the problem that no chip 1C is present in the pockets 90a of the lower tray 90, and, hence, it is impossible to pick up any chip. On the other hand, in this second embodiment, since the chips 1C remain affixed and fixed to the tape 27a also when their back surfaces are checked, the chips 1C do not remain affixed to the back surface (ceiling surface) of the upper tray 27 when the tray is restored to its original state. Accordingly, when the upper tray 27 is removed in its original state, as mentioned above, at the stage of picking up a chip 1C from the tray 27, there does not occur such an inconvenience as no chip 1C being present in the lower tray, thus permitting the chip 1C to be picked up in a satisfactory manner.

### Third Embodiment

In connection with this third embodiment, a modification of the wafer thickness measuring step 102A2 shown in FIG. 1 will be described. FIG. 43 illustrates a wafer thickness measuring step according to this third embodiment.

In this third embodiment, the thickness of the wafer 1W is measured using a thickness gauge 30 beforehand in an off-line manner and the data obtained is transferred to the rear surface processing apparatus. In the same apparatus, the back surface height of the wafer 1W placed on the vacuum chuck stage is detected, and the wafer back surface is subjected to grinding and polishing by a required quantity taking the measured value of the wafer thickness into account. According to this third embodiment, it is possible to eliminate the need for use of an expensive IR camera.

### Fourth Embodiment

In connection with this fourth embodiment, a description will be given concerning another modification of the wafer thickness measuring step 102A2 shown in FIG. 1. FIG. 44 illustrates a wafer thickness measuring step according to this fourth embodiment.

In this fourth embodiment, the thickness of the tape 3a is measured directly by the IR camera 5a or the thickness gauge 30, and the data obtained is transferred to the rear surface processing apparatus. In the same apparatus, the back surface height of the wafer 1W on the vacuum chuck stage 4 is detected, and the thickness of the wafer 1W is calculated on the basis of the detected value and the thickness of the tape 3a. Then, using the upper surface of the vacuum chuck stage 4 as a zero reference, the wafer back surface is subjected to grinding and polishing by a required quantity.

### Fifth Embodiment

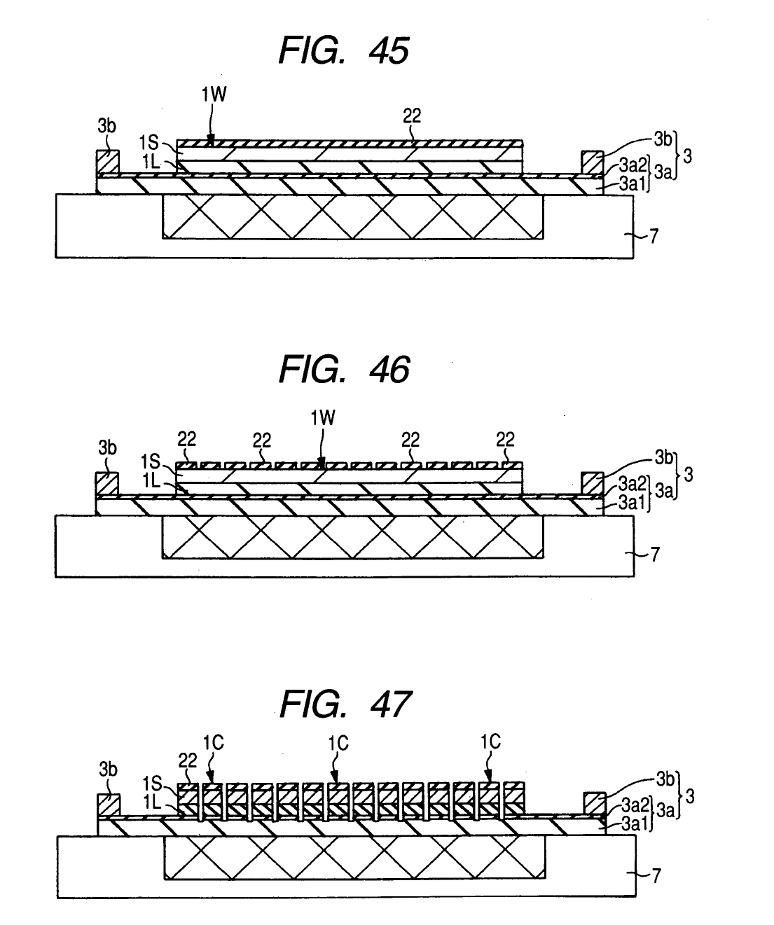

In connection with this fifth embodiment a description will be given about a dicing process in case of affixing a die attaching film to the wafer back surface. FIGS. 45 to 47 are sectional views of a wafer 1W as seen during manufacture of a semiconductor device according to this fifth embodiment.

First, as shown in FIG. 45, a die attaching film 22 is affixed to a back surface of the wafer 1W. The die attaching film 22 is formed using an adhesive resin material, such as, for example, an epoxy resin or a polyimide resin and an electrically conductive filler incorporated therein. It is an adhesive for fixing chips to a lead frame or a wiring board. Then, dicing is performed on the basis of pattern data on a main surface of the wafer 1W obtained in the same way as in the first embodiment. In this dicing process, using a double-shaft dicer, for example, the die attaching film 22 is cut with a single-shaft blade, as seen in FIG. 46, and, thereafter, the wafer 1W is cut with a double-shaft blade having a smaller edge width (cutting width) than that of the single-shaft blade as seen in FIG. 47. A laser beam may be used to cut the die attaching film 22. According to this fifth embodiment, it is possible to provide a chip 1C with the die attaching film 22 affixed to the back surface thereof.

Although the present invention has been described above on the basis of various embodiments thereof, it goes without saying that the present invention is not limited to the above-described embodiments, but that various changes may be made within a scope not departing from the gist of the invention.

Although the present invention has been described above mainly with respect to a case where it is applied to the semiconductor device manufacturing method as the background application field of the invention, no limitation is made thereto, but the present invention also has application to various other methods, e.g., a micromachine manufacturing method.

The present invention is applicable to the semiconductor device manufacturing industry.

1. A method of manufacturing a semiconductor device, comprising the steps of:
(a) providing a semiconductor wafer having a main surface and a back surface opposite to the main surface;
(b) forming semiconductor chips having semiconductor elements over the main surface of the semiconductor wafer;
(c) affixing a tape having a frame portion along an outer periphery thereof to the main surface of the semiconductor wafer;
(d) in the state of the tape affixed to the main surface of the semiconductor wafer, grinding and thereafter polishing the back surface of the semiconductor wafer;
(e) in the state of the tape affixed to the main surface of the semiconductor wafer, cutting the semiconductor wafer to divide the wafer into the individual semiconductor chips; and
(f) taking out the semiconductor chips after the step (e).

2. A method according to claim 1, further comprising, before the step (d), a step of measuring the thickness of the semiconductor wafer affixed to the tape.

3. A method according to claim 1, wherein the step (e) comprises the steps of:
(e1) recognizing a cutting region over the main surface of the semiconductor wafer; and
(e2) after the step (e1), applying a cutting edge to the cutting region from the back surface side of the semiconductor wafer and cutting the wafer.

4. A method according to claim 3, wherein, in the step (e1), the cutting region over the main surface of the semiconductor wafer is recognized from the back surface of the semiconductor wafer with use of an infrared camera

5. A method according to claim 1, wherein the step (e) comprises the steps of:
(e1) recognizing a cutting region over the main surface of the semiconductor wafer;
(e2) applying a laser beam to the cutting region from the back surface side of the semiconductor wafer with use of pattern data of the cutting region obtained in the step (e1) to form a modified layer in the interior of the semiconductor wafer; and
(e3) cutting the semiconductor wafer by stretching the tape.

6. A method according to claim 5, wherein, in the step (e1), the cutting region over the main surface of the semiconductor wafer is recognized from the back surface side of the semiconductor wafer with use of an infrared camera.

7. A method according to claim 1, wherein the step (e) comprising the steps of:
(e1) recognizing a cutting region over the main surface of the semiconductor wafer;
(e2) forming a die attach layer over the back surface of the semiconductor wafer;
(e3) after the step (e1), applying a first cutting edge to the die attach layer in the cutting region of the semiconductor wafer and cutting the wafer; and
(e4) applying a second cutting edge smaller in width than the first cutting edge to the cutting region from the back surface side of the semiconductor wafer and cutting the wafer with use of pattern data of the cutting region obtained in the step (e1).

8. A method according to claim 1, wherein, in the step (f), the tape is sucked from a back surface side thereof opposite to the surface thereof as a main surface to which the main surface of the semiconductor wafer is affixed, thereby changing the state of contact between the main surface of the tape and the main surface of the semiconductor chip concerned from surface contact to point contact, and taking out the semiconductor chip in this state.

9. A method according to claim 1, further comprising the steps of:
(g) after taking out the semiconductor chips in the step (f), affixing the semiconductor chips to a pressure-sensitive adhesive tape in a conveyance tray; and
(h) conveying the semiconductor chips as affixed to the pressure-sensitive adhesive tape in the conveyance tray to a predetermined place.

10. A method according to claim 9, wherein the pressure-sensitive adhesive tape in the conveyance tray has a property such that the adhesion thereof is deteriorated upon exposure to ultraviolet light.

11. A method according to claim 9, wherein the pressure-sensitive adhesive tape in the conveyance tray is affixed to the conveyance tray removably.

12. A method according to claim 9, wherein the pressure-sensitive adhesive tape in the conveyance tray is transparent.

13. A method according to claim 1, further comprising the step of:
(g) after taking out the semiconductor chips in the step (f), mounting each of the semiconductor chips over a predetermined substrate.

14. A method according to claim 1, wherein the thickness of the semiconductor wafer after the step (d) is 100 μm or less.

15. A method of manufacturing a semiconductor device, comprising the steps of:
(a) providing a semiconductor wafer having a main surface and a back surface opposite to the main surface;
(b) forming semiconductor chips having semiconductor elements over the main surface of the semiconductor wafer;
(c) affixing a tape having a frame portion along an outer periphery thereof to the main surface of the semiconductor wafer;
(d) in the state of the tape affixed to the main surface of the semiconductor wafer, grinding and thereafter polishing the back surface of the semiconductor wafer; and
(e) shipping the semiconductor wafer after the step (d) to the exterior, with the tape affixed to the main surface of the semiconductor wafer.

16. A method according to claim 15, further comprising, as steps carried out in the exterior, the steps of:
(f) cutting the semiconductor wafer to divide the wafer into the individual semiconductor chips, with the tape affixed to the main surface of the semiconductor wafer; and
(g) taking out the semiconductor chips after the step (f).

17. A method of manufacturing a semiconductor device, comprising the steps of:
(a) providing a semiconductor wafer having a main surface and a back surface opposite to the main surface;
(b) forming semiconductor chips having semiconductor elements over the main surface of the semiconductor wafer;
(c) affixing a tape having a frame portion along an outer periphery thereof to the main surface of the semiconductor wafer;
(d) in the state of the tape affixed to the main surface of the semiconductor wafer, grinding and thereafter polishing the back surface of the semiconductor wafer;
(e) in the state of the tape affixed to the main surface of the semiconductor wafer, cutting the semiconductor wafer to divide the wafer into the individual semiconductor chips; and
(f) shipping the semiconductor wafer after the step (e) to the exterior, with the tape affixed to the main surface of the semiconductor wafer.

18. A method according to claim 17, further comprising, as steps carried out in the exterior, the steps of:
(g) taking out the semiconductor chips after the step (f) and mounting each of the semiconductor chips over a predetermined substrate.

19. A method of manufacturing a semiconductor device, comprising the steps of:
(a) providing a semiconductor wafer having a main surface and a back surface opposite to the main surface;
(b) forming semiconductor chips having semiconductor elements over the main surface of the semiconductor wafer;
(c) grinding and thereafter polishing the back surface of the semiconductor wafer;
(d) cutting the semiconductor wafer to divide the wafer into the individual semiconductor chips;
(e) taking out the semiconductor chips after the step (d) and affixing them to a pressure-sensitive tape in a conveyance tray; and
(f) conveying the semiconductor chips with affixed to the pressure-sensitive tape in the conveyance tray to a predetermined place.

20. A method according to claim 19, wherein the step (e) comprises a step of conveying each of the semiconductor chips after the step (d) to a predetermined position in the conveyance tray while chucking the semiconductor chip by vacuum chuck means, the releasing the vacuum chuck condition of the vacuum chuck means, and reverse-injecting air, thereby causing the semiconductor chip to separate from the vacuum chuck means and drop to the pressure-sensitive adhesive tape side in the conveyance tray.

21. A method according to claim 19, wherein the pressure-sensitive adhesive tape in the conveyance tray has a property such that the adhesion thereof is deteriorated upon exposure to ultraviolet light.

22. A method according to claim 19, wherein the pressure-sensitive adhesive tape in the conveyance tray is affixed to the conveyance tray removably.

23. A method according to claim 19, wherein the pressure-sensitive adhesive in the conveyance tray is transparent, and the back surfaces of the semiconductor chips are checked through the pressure-sensitive tape in the conveyance tray.

24. A method according to claim 19, further comprising a step of, after taking out the semiconductor chips from the conveyance tray, mounting each of the semiconductor chips over a predetermined substrate.

25. A method according to claim 19, wherein a polyimide resin film is formed over the main surface of each of the semiconductor chips.

26. A method according to claim 19, wherein the thickness of the semiconductor wafer after the step (c) is 100 μm or less.
